(19) United States
(12) Patent Application Publication
(10) Pub. No.: US 2005/0205951 A1
(43) Pub. Date: Sep. 22, 2005

(54) Flip chip bonded micro-electromechanical system (MEMS) device

(75) Inventor: Mark H. Eskridge, Renton, WA (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell Internatioanl, Inc., Morristown, NJ (US)

(21) Appl. No.: 10/804,609

(22) Filed: Mar. 18, 2004

(51) Int. Cl. H01L 29/84

(52) U.S. Cl. 257/416; 257/417

(57) ABSTRACT

A micro-electromechanical system (MEMS) device having a pair of spaced apart top and bottom substrates or cover plates having mutually opposing inner surfaces structured to cooperate with a micro-machined electromechanical device mechanism, such as a micro-machined sensor or actuator mechanism. Such a micro-machined electromechanical device mechanism is coupled to the inner surface of one of the top and bottom substrates. A metal chip bond pad is formed on the inner surface of the bottom substrate and is electrically coupled to an electrical path; another metal chip bond pad formed on the inner surface of the top substrate in a complementary position opposite the chip bond pad on the bottom substrate; and an electrically conductive gold stud bump is mechanically and electrically coupled between the metal chip bond pads on the top and bottom substrates.

### FIELD OF THE INVENTION

The present invention relates generally to devices fabricated as micro-electromechanical system (MEMS) devices and methods for manufacturing the same, and in particular to double-sided MEMS devices and methods for both mechanically attaching operational protective covers to MEMS devices and routing signals therethrough.

### BACKGROUND OF THE INVENTION

Many devices fabricated as micro-electromechanical systems (MEMS), both sensor and actuator devices, and methods for manufacturing the same are generally well-known. See, for example, U.S. patent application Ser. No. 09/963,142, METHOD OF TRIMMING MICRO-MACHINED ELECTROMECHANICAL SENSORS (MEMS) DEVICES, filed in the name of Paul W. Dwyer on Sep. 24, 2001, which is assigned to the assignee of the present application and the complete disclosure of which is incorporated herein by reference, that describes a MEMS acceleration sensor and method for manufacturing the same. In another example, U.S. Pat. No. 6,428,713, MEMS SENSOR STRUCTURE AND MICROFABRICATION PROCESS THEREFORE, issued to Christenson, et al. on Aug. 6, 2002, which is incorporated herein by reference, describes a capacitive acceleration sensor formed in a semiconductor layer as a MEMS device. Other known MEMS devices include, for example, micro-mechanical filters, pressure sensors, gyroscopes, resonators, actuators, and rate sensors, as described in U.S. Pat. No. 6,428,713.

Vibrating beam acceleration sensors formed in a silicon substrate as MEMS devices are also generally well-known and are more fully described in each of U.S. Pat. No. 5,334,901, entitled VIBRATING BEAM ACCELEROMETER; U.S. Pat. No. 5,456,110, entitled DUAL PENDULUM VIBRATING BEAM ACCELEROMETER; U.S. Pat. No. 5,456,111, entitled CAPACITIVE DRIVE VIBRATING BEAM ACCELEROMETER; U.S. Pat. No. 5,948,981, entitled VIBRATING BEAM ACCELEROMETER; U.S. Pat. No. 5,996,411, entitled VIBRATING BEAM ACCELEROMETER AND METHOD FOR MANUFACTURING THE SAME; and U.S. Pat. No. 6,119,520, entitled METHOD FOR MANUFACTURING A VIBRATING BEAM ACCELEROMETER, the complete disclosures of which are incorporated herein by reference. Such vibrating beam accelerometers have been fabricated from a body of semiconductor material, such as silicon, using MEMS techniques. Existing techniques for manufacturing these miniature devices are described in U.S. Pat. No. 5,006,487, entitled METHOD OF MAKING AN ELECTROSTATIC SILICON ACCELEROMETER, and U.S. Pat. No. 4,945,765, entitled SILICON MICRO-MACHINED ACCELEROMETER, the complete disclosures of which are incorporated herein by reference.

As is generally well-known, a typical MEMS device, whether a sensor or an actuator, has a size on the order of less than 10⁻³ meter, and may have feature sizes of 10⁻⁶ to 10⁻³ meter. Moving parts within a device are typically separated by microscopically narrow critical gap spacings, and as such are highly sensitive to particle contamination, such as dust and other microscopic debris. MEMS devices are also sensitive to contamination arising from corrosive environments; humidity and H₂O in either the liquid or vapor phase, which may cause stiction problems in the finished device; and mechanical damage such as abrasion. MEMS devices are often required to operate at a particular pressure or in a vacuum; or in a particular liquid or gas such as, for example, dry nitrogen; and in different acceleration environments from high-impact gun barrel munitions to zero gravity deep space applications. Such application environments aggravate the device sensitivity to contamination.

The manufacture of MEMS devices includes many individual processes. Each of the individual processes may expose the device to a source of contamination. This sensitivity to particle contamination poses a challenge to the structural design and microfabrication processes associated with these small-scale, intricate and precise devices in view of the desire to have fabrication repeatability, fast throughput times, and high product yields from high-volume manufacturing. MEMS devices are typically encapsulated and sealed within a microshell, i.e., between cover plates. The microshell serves many purposes, including shielding the micro-mechanical parts of the MEMS device from damage and contamination.

Traditionally, MEMS devices utilize a wafer stack or “sandwich” design of two or three stacked semiconductor silicon wafers, with the sensor or actuator device mechanism wafer being positioned in the center between two outside cover wafers or “plates” in a three-wafer device. The cover plates are formed, for example, in respective silicon wafers. Alternatively, the cover plates are formed in respective Pyrex R™ glass wafers.

In a two-wafer device, a single protective cover plate is mounted on top of the mechanism wafer. The cover plate is bonded to the mechanism wafer in a three dimensional MEMS device. A frit glass seal or another conventional mechanism bonds the cover plate to the device along their common outer edges or peripheries. Other common bonding mechanisms include, for example, eutectic metal-to-metal bonding, silicon-to-silicon fusion bonding, electrostatic silicon-to-silicon dioxide bonding, and anodic bonding for silicon-to-glass bonds. The cover plate or plates act as mechanical stops for movable portions of the device mechanism, thereby protecting the device mechanism from forces that would otherwise exceed the mechanism's mechanical limits.

Electrical connections to the sensitive portions of the device mechanism typically require one or more bond wires that pass through window apertures in one cover plate and connect to conductive paths formed on the surface of the device substrate containing the device mechanism. These conductive paths and the corresponding windows in the cover plate have traditionally been located within the interiors of the respective device and cover substrates, thus being interior of the seals that bond the cover plates to the device along their respective peripheral edges. These internal windows may allow particulate contamination or moisture to invade the interior of the MEMS device during handling, transportation, testing or wire bonding operations, which can result in premature failure.

FIGS. 1 and 2 are plan and cross-sectional side views, respectively, of a first known conventional MEMS device 10 having the conventional conductive paths for routing signals into and out of MEMS devices. In FIG. 1 the prior art MEMS device 10 is shown open, i.e., without its top cover plate and with the MEMS sensor or actuator device mechanism removed for clarity. The prior art MEMS device 10 includes a MEMS sensor or actuator device mechanism bonded to the inner surface 12 of a device substrate 14 indicated generally at 16. As illustrated in FIG. 2, the MEMS device mechanism is formed in an interior portion of a mechanism layer 18, which is an epitaxial layer of semiconductor silicon formed on or adhered to the device substrate 14. The device substrate 14 also operates as a device bottom cover plate.

As illustrated in FIG. 2, the device substrate or bottom cover plate 14 and a protective top substrate or cover plate 20 and are typically sized to cover at least the device mechanism 16 and a peripheral frame portion 22 of the epitaxial silicon mechanism layer 18 from which the device mechanism 16 is suspended and which spaces the cover plates 20, 14 from the mechanism layer 18 and the device mechanism 16. Alternatively, the peripheral frame portion 22 for spacing the top and bottom cover plates 20, 14 is a plurality of mesas formed in one of the cover plates in a pattern around the device mechanism 16, either as a continuous mesa (shown) or a plurality of individual mesas, as is well-known in the art and discussed herein. One or more signal paths embodied as electrical conductors 24, usually gold traces, are formed on an inner surface 12 of the bottom cover plate 14 and arranged for being electrically interconnected to with the device mechanism 16 by means well-known in the art. The electrical conductors 24 extend outwardly across the inner surface 12 of the bottom cover plate 14 to different conventional metal wire bond pads 26 that are positioned on the surface 12 of the bottom cover plate 14 outside the area occupied by the device mechanism 16. The electrical conductors 24 thus provide remote electrical access to the device mechanism 16.

The top and bottom cover plates 20, 14 are bonded or otherwise adhered to respective top and bottom surfaces 28, 30 of the mechanism layer 18. The top and bottom cover plates 20, 14 each have a respective substantially planar inner surface 32, 12 that is bonded to the respective top and bottom surfaces 28, 30 of the mechanism layer 18 using an appropriate conventional bonding mechanism 34 that is provided in a pattern in between the top cover plate 20 and the top surface 28 of the epitaxial silicon mechanism layer 18, and between the bottom cover plate 14 and the mechanism wafer bottom surface 30. The bonding mechanism 34 is, for example, an adhesive bonding agent in a pre-form of glass frit, a eutectic metal-to-metal bond, a silicon-to-glass anodic bond, or an electrostatic silicon-to-silicon dioxide bond, as appropriate. The pattern of the bonding mechanism 34 is typically external to and may completely surround the device mechanism 16 and the wire bond pads 26.

As illustrated in FIG. 2, the top cover plate 20 is sized to cover at least the device mechanism 16 and the wire bond pads 26. Of necessity, a quantity of pass-through window apertures 36 are formed in the top cover plate 20 in alignment with the wire bond pads 26. In practice, the MEMS device 10 is cut out after the cover plates 20, 14 have been installed, so that the three stacked wafers, i.e., the device mechanism layer 18 and the cover plates 20, 14, are all the same size, and the epitaxial silicon mechanism layer 18 is completely and exactly covered by the top cover plate 20 (in a two-wafer stack) and the bottom cover plate 14 (in a three-wafer stack). The pass-through window apertures 36 in the top cover plate 20 provide access for connecting electrical wires 38 to the bond pads 26 on the inner surface 12 of the bottom cover plate 14 for routing signals into and out of the device mechanism 16.

The pass-through window apertures 36 in the top cover plate 20 of the prior art device 10 illustrated in FIGS. 1 and 2 are located within the interior of the seals provided by bonding mechanisms 34 that bond the cover plates 20, 14 to the mechanism layer 18 along their respective peripheral edges. These internal apertures 36 can allow particulate contamination or moisture to invade the interior of the MEMS device 10 during handling, transportation, testing or wire bonding operations, which can result in premature failure.

FIGS. 3 and 4 are plan and cross-sectional side views, respectively, of a second conventional MEMS device 40 of the prior art solution to the contamination problems inherent in the device 10 of FIGS. 1 and 2. The prior art MEMS device 40 has the conventional gold trace conductive paths 24 extended to a quantity of the conventional metal wire bond pads 26 positioned outside the seal 34 of the top cover 20. In FIG. 3 the MEMS device 40 is shown open, i.e., without its top cover 20, and with the MEMS sensor or actuator device mechanism 16 removed for clarity. The MEMS device 40 includes a MEMS sensor or actuator device mechanism that is formed in the interior portion of the epitaxial silicon mechanism layer 18, suspended from the mechanism wafer peripheral frame portion 22 and bonded to the inner surface 12 of the bottom cover plate 14 indicated generally at 16.

The gold traces of electrical conductors 24 are formed on the inner surface 12 of the bottom substrate or cover plate 14. The electrical conductors 24 are electrically interconnected to the device mechanism 16 and extend outwardly across the inner surface 12 of the bottom cover plate 14 to the metal wire bond pads 26 that are positioned on the bottom cover plate inner surface 12 remote from the device mechanism 16 and which thereby provide remote electrical access to the device mechanism 16.

As illustrated in FIG. 4, the top and bottom cover plates 20, 14 are bonded or otherwise adhered to respective top and bottom surfaces 28, 30 of the mechanism layer 18. The cover plates 20, 14 are formed having respective surfaces 32, 12 that are bonded to the respective top and bottom surfaces 28, 30 of the mechanism layer 18 using an appropriate conventional bonding technique. The bottom cover plate 14 is sized to cover at least the device mechanism 16 and the supporting peripheral frame portion 22. The top cover plate 20 is sized to cover at least the device mechanism 16 and the supporting peripheral frame portion 22 while exposing the wire bond pads 26 on the bottom cover 14. The pass-through window apertures 36 in the top cover plate 20 are aligned with the wire bond pads 26 on the bottom substrate or cover plate 14, and thereby provide access for connecting electrical wires 38.

The pattern of the bonding mechanism 34 includes a portion 34a that lies between the device mechanism 16 and the wire bond pads 26 and overlies a portion of the electrical conductors 24. The wire bond pads 26 thus lie outside the pattern of the bonding mechanism 34 surrounding the device mechanism 16. The window apertures 36 in the top cover plate 20 also lie outside the confines of the pattern of the bonding mechanism 34. When the MEMS device 10 is formed as a silicon-on-insulator (SOI) MEMS device, having a silicon MEMS device mechanism either mounted on an oxide layer over a bulk silicon cover plate or patterned in epitaxial silicon layered over the oxide layer, the bonding mechanisms 34, 34a are optionally silicon-to-silicon fusion bonds.

The bonding mechanism 34 is optionally conventional anodic bonding when the cover plates 20, 14 are formed in respective Pyrex R™ glass wafers which is a well-known glass with a thermal expansion coefficient well matched to that of silicon. Anodic bonding can also be performed using thin glass films deposited by sputtering on a silicon substrate. Anodic bonding, however, fails to seal between the bottom cover plate 14 and the gold of the electrical conductors 24. The electrical conductors 24 thus prevent the bonding mechanism 34 from forming a hermetic seal.

Also, as illustrated in FIG. 4, the gold traces of the electrical conductors 24 are typically partially submerged beneath the bottom cover plate inner surface 12 in shallow troughs 42 etched in the cover plate inner surface 12. The partially submerged gold traces 24 also extend above the cover plate inner surface 12 by a small amount which may be on the order of 500 to 1000 Angstroms. Although small, this irregularity in the bottom cover plate inner surface 12 detracts from the seal by holding the inner surface 32 of the top cover plate 20 away from the bottom surface 30 of the mechanism layer 18 so that no seal is formed in the immediate vicinity of the gold traces 24.

An alternative solution is disclosed in U.S. patent application Ser. No. 10/226,518, HERMETICALLY SEALED SILICON MICRO-MACHINED ELECTROMECHANICAL SYSTEM (MEMS) DEVICE HAVING DIFFUSED CONDUCTORS, filed in the name of Stephen C. Smith on Aug. 22, 2002, which is assigned to the assignee of the present application and the complete disclosure of which is incorporated herein by reference, wherein a hermetically sealed sensor or actuator device mechanism is electrically interconnected by diffused conductive paths to a plurality of wire bond pads that are located external to the hermetic seal.

Still another alternative solution is disclosed in U.S. patent application Ser. No. 10/746,463, SIGNAL ROUTING IN A HERMETICALLY SEALED MEMS DEVICE, filed in the names of Mark H. Eskridge and Peter Cousseau on Dec. 24, 2003, which is assigned to the assignee of the present application and the complete disclosure of which is incorporated herein by reference, wherein a hermetically sealed sensor or actuator device mechanism is electrically interconnected by a plurality of pillars of semiconductor silicon coupled between corresponding windows formed through the cover plate and electrical traces on the interior of the cover plate.

As discussed in detail herein above, electrical signals into and out of the MEMS device 10 are routed through the wire bond pads 26 and electrical wires 38. Without reference to manufacturing difficulties, at least because MEMS devices 10 are typically placed as die on a circuit board or other substrate that supplies the device power and signal conditioning and circuitry that uses the device output, access to the wire bond pads 26 is only from above the device 10. Therefore, the wire bond pads 26 are limited to the single inner surface 12 of the bottom substrate or cover plate 14 due to the access limitations. Signals into and out of the device mechanism 16 are similarly limited to the inner surface 12 of the bottom substrate 14 along the signal paths embodied as electrical conductors 24 formed on the substrate inner surface 12. Thus, all signals into and out of the device mechanism 16 must be routed on the device mechanism bottom surface 30. While communication with the device mechanism bottom surface 30 is accommodated, communication with the device mechanism upper surface 28 must be by electrical paths coupled through the bottom surface 30.

Furthermore, communication with the top substrate or cover plate 20 must also be routed through the electrical conductors 24 and wire bond pads 26 on the inner surface 12 of the bottom substrate 14. Because the top substrate 20 is spaced away from the bottom substrate 14 by the mechanism layer 18, any communication with top substrate 20 must be routed through the device mechanism 16 or the mechanism layer 18 generally. These signal routing limitations demand very complex designs to accommodate communication with the upper device mechanism and substrate surfaces 28, 32. As a result, the top half of the device 10 is often unused, and the top substrate 20 is provided only as a protective cover to protect the delicate device mechanism 16 from breakage and contamination.

In some MEMS devices these signal routing limitations limit their performance as sensors. For example, the inability to communicate with one side of the device causes it to have asymmetric response which tends to degrade performance, particularly in a vibration environment. MEMS devices that depend for response on capacitance between the device mechanism 16 and electrodes on the cover plates 14, 20 must be much larger to account for the reduction in capacitive area when capacitive area on the top plate 20 is not available because of the communication limitations. Additionally, the inability to provide the restoring forces of electrostatic attraction between the top surface 28 of the device mechanism 16 and the top cover plate 20 because of the communication limitations increases the complexity of closed-loop sensor designs.

### SUMMARY OF THE INVENTION

The present invention provides a micro-electromechanical system (MEMS) device that overcomes limitations of the prior art by providing conductive stud bumps on chip bond pads for communicating between opposing top and bottom surfaces of the device. Accordingly, a MEMS device is formed of a pair of spaced apart top and bottom substrates or cover plates having mutually opposing inner surfaces structured to cooperate with a micro-machined electromechanical device mechanism, such as a micro-machined sensor or actuator mechanism. Such a micro-machined electromechanical device mechanism is coupled to the inner surface of one of the top and bottom substrates. A metal chip bond pad is formed on the inner surface of the bottom substrate and is electrically coupled to an electrical path; another metal chip bond pad formed on the inner surface of the top substrate in a complementary position opposite the chip bond pad on the bottom substrate; and an electrically conductive gold stud bump is mechanically and electrically coupled between the metal chip bond pads on the top and bottom substrates.

According to another aspect of the invention, the top and bottom metal substrates are symmetrically spaced from respective active surfaces of the micro-machined electromechanical device.

According to another aspect of the invention, a conventional metal wire bond pad may be formed on the inner surface of the bottom substrate remote from the device mechanism and electrically coupled to the electrical path for routing signals into and out of the MEMS device. Optionally, an electrical path is formed on the inner surface of the top substrate and is electrically coupled to the chip bond pad of the top substrate. In such instance, the electrical path formed on the inner surface of the top substrate is optionally electrically coupled to an upper surface of the device mechanism. Additionally, the electrical path formed on the inner surface of the bottom substrate may be electrically coupled to a lower surface of the device mechanism, whereby signals are routed between the upper and lower surfaces of the device mechanism.

According to another aspect of the invention, the MEMS device includes a mesa formed between the inner surfaces of the top and bottom substrates. The mesa may be formed on the inner surface of one or both of the top and bottom substrates. According to another aspect of the invention, the mesa is formed as a continuous mesa completely surrounding the device mechanism. Optionally, a hermetic seal is formed between the mesa and the inner surface of one of the opposing substrate.

According to another aspect of the invention, the MEMS device is a capacitive acceleration sensor wherein a semiconductor silicon mechanism substrate is mechanically coupled to the inner surfaces of one of the top and bottom substrates and has a micro-machined capacitive acceleration sensor mechanism patterned therein. One or more electrodes is formed on each of the first and second mutually opposing inner substrate surfaces, and pairs of complementary metal chip bond pads are formed on the first and second mutually opposing inner substrate surfaces. An electrically conductive path is formed between at least one of the electrodes and one of the chip bond pads on a corresponding one of the first and second mutually opposing inner substrate surfaces. One of the gold stud bumps is electrically and mechanically coupled between each of the pairs of complementary metal chip bond pads. Additionally, one or more mesas spaces the electrodes on the top and bottom mutually opposing inner substrate surfaces substantially symmetrically from respective upper and lower surfaces of the capacitive acceleration sensor mechanism.

According to another aspect of the invention, an electrically conductive path is coupled between the capacitive acceleration sensor mechanism and at least one of the chip bond pads. Additionally, a plurality of wire bond pads formed is on one of the top and bottom mutually opposing inner substrate surfaces; and an electrically conductive path is formed between at least one of the chip bond pads and at least one of the wire bond pads.

According to another aspect of the invention, the semiconductor silicon mechanism substrate having the micro-machined capacitive acceleration sensor mechanism patterned therein is mechanically coupled to the inner surface of the top substrate; the one or more mesas extend from the inner surface of the top substrate; and the plurality of wire bond pads are formed on the inner surface of the bottom substrate in an area remote from the sensor mechanism.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a plan view of a first conventional MEMS device of the prior art having conventional conductive paths for routing signals into and out of MEMS devices;

FIG. 2 is a cross-sectional side view of the prior art MEMS device illustrated in FIG. 1;

FIG. 3 is a plan view of another conventional MEMS device of the prior art having conventional conductive paths for routing signals into and out of MEMS devices;

FIG. 4 is a cross-sectional side view of the prior art MEMS device illustrated in FIG. 3;

FIG. 5 is a plan view of the MEMS device of the invention with the top cover plate removed for clarity and having a plurality of electrically conductive stud bumps formed on individual electrical interconnection areas for forming electrically conductive paths between the top and bottom portions of the device while mechanically attaching the top substrate or cover plate to the bottom substrate or cover plate;

FIG. 6 is a bottom plan view of the MEMS device of the invention with the bottom cover plate removed for clarity and having a plurality of individual electrical interconnection areas for forming electrical and mechanical bonds with the electrically conductive stud bumps;

FIG. 7 is a cross-sectional side view of the MEMS device of the invention which illustrates the electrical interconnection areas and electrically conductive stud bumps for routing of signals into and out of the top surface of the MEMS device mechanism while mechanically attaching the top substrate or cover plate to the bottom substrate or cover plate;

FIG. 8 is a cross-sectional side view of the MEMS device of the invention which illustrates the electrical interconnection areas and electrically conductive stud bumps for routing of signals into and out of the inner surface of the MEMS device top substrate or cover plate while mechanically attaching the top substrate or cover plate to the bottom substrate or cover plate; and

FIG. 9 is an upward-looking bottom plan view of the MEMS device of the invention embodied with both the gold ball stud bumps and the device mechanism provided on the top substrate or cover plate.

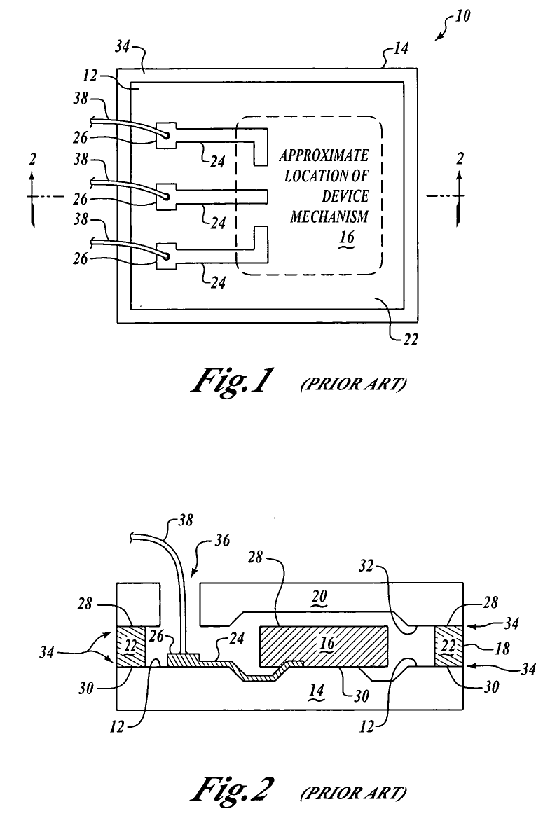

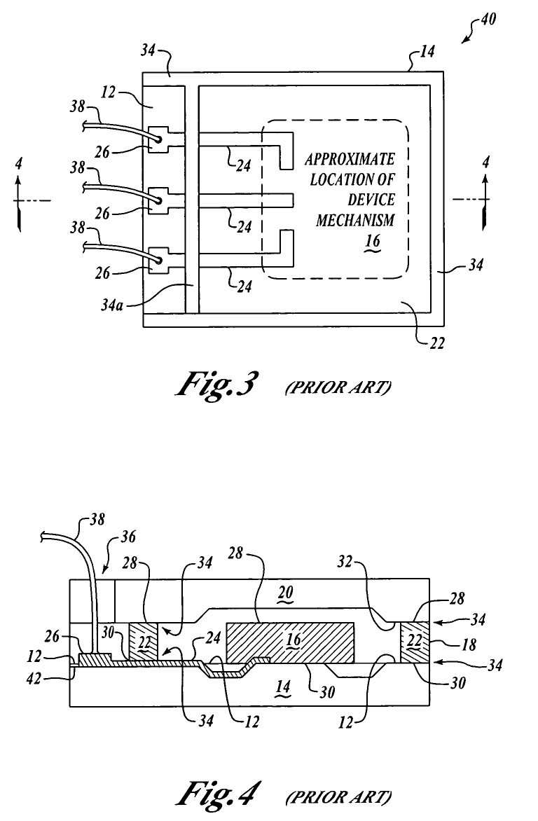

### DETAILED DESCRIPTION OF PREFERRED EMBODIMENT

In the Figures, like numerals indicate like elements.

The present invention is an apparatus and method for communicating between opposing top and bottom surfaces of micro-electromechanical system (MEMS) devices by means of a plurality of conductive stud bumps on chip bond pads.

The use of conductive stud bumps on chip bond pads is well-known in the electronics industry for making electrical connections in microelectronic assemblies. Flip chip microelectronic assembly is the formation of direct electrical connection of face-down electronic components onto substrates, circuit boards, or carriers, by means of conductive bumps on chip bond pads. The flip chip technology, also known as Direct Chip Attach (DCA), replaces older wire bonding technology in semiconductor device assemblies which uses face-up chips with wire connections to the bond pads. Furthermore, wire bond connections are limited to the perimeter of the die, while flip chip connections can be made anywhere on the die. Flip chip electrical connections also accommodate three-dimensional stacking of die and other components.

Flip chip assemblies are made in three stages: the die or wafer is “bumped,” the bumped die or wafer is attached to the board or substrate, and optionally, space remaining under the die is filled remaining with an electrically non-conductive material, e.g., an epoxy. Different kinds of flip chip assemblies are differentiated by the conductive bump, the attachment materials, and the processes used. Cost, space and performance constraints of the present invention are best suited by the well-known gold “stud bump” flip chip process.

As is well-known in the art, the gold stud bump flip chip process bumps die using a modified standard wire bonding technique. This technique makes a conventional gold ball for wire bonding by melting the end of a gold wire to form a sphere. The gold ball is attached to the chip bond pad as the first part of a wire bond. To form gold bumps instead of wire bonds, the wire bonder machine is modified to break off the wire after attaching the ball to the chip bond pad. The gold ball, or “stud bump” remaining on the bond pad provides a pennanent mechanical and electrical connection through the bond pad. Thereafter, the gold stud bump flip chips may be attached to bond pads on a substrate with adhesive or by thermosonic or thermocompressive gold-to-gold connection.

The bumping equipment, either a wire bonder machine or a dedicated stud bumper, for the gold stud bump process is widely available and well characterized. Since stud bumps are formed by wire bonders, they can be placed anywhere a wire bond might be placed. The gold stud bump flip chip process is known to easily achieve pitches of less than 100 microns and the gold ball can be placed on pads of less than 75 microns. Thus, the gold stud bump process is ideal for forming the pattern of electrically conductive stud bumps on chip bond pads according to the present invention for communicating between opposing top and bottom surfaces of micro-electromechanical system (MEMS) devices.

Since stud bumping can be done on a wire bonder machine, the process does not require wafers or under-bump metallization (UBM). Thus, off-the-shelf die can be bumped without pre-processing.

Stud bumping is a serial process so that time required increases with the number of bumps. However, current high speed equipment can place as many as 12 bumps per second, but requires precise die placement equipment because stud bumping has a low tolerance for placement errors.

Accordingly, the apparatus and method of the invention are realized in an environmentally sealed MEMS device having a micro-machined electromechanical device mechanism formed of semiconductor silicon and a pair of spaced apart top and bottom substrates or “cover plates,” the cover plates being made either of respective Pyrex R™ glass wafers or of silicon substrates having thin glass inner surfaces deposited thereon of a type that are known to be suitable for forming anodic silicon-to-glass bonds. According to one embodiment of the invention, the cover plates are silicon cover plates, which permits the MEMS device to be manufactured as a silicon-on-insulator (SOI) chip, as described by Zosel, et al. in U.S. Pat. No. 6,661,070, entitled MICROMECHANICAL AND MICROOPTOMECHANICAL STRUCTURES WITH SINGLE CRYSTAL SILICON EXPOSURE STEP, issued on Dec. 9, 2003, which is incorporated herein by reference and teaches a method for defining a MEMS device structure on a single crystal silicon layer separated by an insulator layer from a silicon substrate layer. Thus, the MEMS sensor or actuator or other device mechanism is either formed in silicon and mounted on an oxide layer over a bulk silicon cover plate, or patterned in epitaxial silicon layered over the oxide layer.

The cover plates have their inner surfaces structured to cooperate with the device mechanism, the inner surface of one of the cover plates being further formed with a plurality of electrical paths, usually conductive gold traces, extended between the device mechanism and a portion of the inner surface remote from the device mechanism. When the MEMS device is formed on a SOI chip, the oxide layer insulates the bond pads and electrical traces from the bulk silicon cover plate.

An appropriate pattern of gold stud bumps on chip bond pads is formed on the inner surface of a first one of the cover plates, the gold stud bumps being compressed between the bond pads on the first cover plate and complementary chip bond pads on the inner surface of the second cover plate.

According to one embodiment of the invention, one or more of the gold stud bumps that form the pattern of gold stud bumps are formed between complementary electrical conductors formed on the inner surfaces of the top and bottom cover plates to pass electrical signals between top and bottom surfaces of the micro-machined electromechanical device mechanism.

According to another embodiment of the invention, one or more of the gold stud bumps that form the pattern of gold stud bumps are optionally formed between electrical conductors formed on the inner surface of the top cover plate to pass electrical signals between the top surface of the micro-machined electromechanical device mechanism and complementary electrical conductors that are led to different conventional metal wire bond pads that are positioned on the inner surface of the bottom cover plate outside the area occupied by the device mechanism. The gold stud bumps thus provide remote electrical access to the top surface of the device mechanism.

According to another embodiment of the invention, one or more of the gold stud bumps that form the pattern of gold stud bumps are optionally formed between conductive electrodes formed on the inner surface of the top cover plate to pass electrical signals between the electrodes on the inner surface of the top cover plate and complementary electrical conductors that are led to different conventional metal wire bond pads that are positioned on the inner surface of the bottom cover plate outside the area occupied by the device mechanism. The gold stud bumps thus provide remote electrical access to the electrodes on the inner surface of the top cover plate of the device.

According to another embodiment of the invention, the pattern of gold stud bumps formed between chip bond pads on the inner surfaces of the top and bottom cover plates operate to mechanically attach the top and bottom cover plates.

According to another embodiment of the invention, the top and bottom cover plates are spaced apart by a plurality of mesas formed on the inner glass surface of either one of the cover plates. According to an alternative embodiment of the invention, the plurality of mesas form an unbroken wall completely surrounding the micro-machined electromechanical device mechanism, and a frit, adhesive or epoxy bonding agent is provided between the mesa wall and the mating cover plate, whereby a peripheral seal ring hermetically seals the device mechanism within the MEMS device. This same arrangement of mesas forming an unbroken wall completely surrounding the device mechanism can be used without any bonding agent to make a non hermetic seal, or “dust cover,” to exclude particulate contamination.

The Figures illustrate by example and without limitation the apparatus and method for communicating between opposing top and bottom surfaces of micro-electromechanical system (MEMS) devices using a plurality of conductive bumps on chip bond pads is embodied in a MEMS sensor or actuator device 100 which is, for example, a capacitive or vibrating beam acceleration sensor or another MEMS device such as an accelerometer, a pressure sensor, a gyroscope, a resonator, an actuator, or a rate sensor, the basic art of which are all generally well-known, or another MEMS sensor or actuator device.

The Figures also illustrate by example and without limitation the apparatus and method for hermetically sealing the MEMS sensor or actuator device 100 having the pattern of conductive bumps on chip bond pads for communicating between opposing top and bottom interior surfaces of the device.

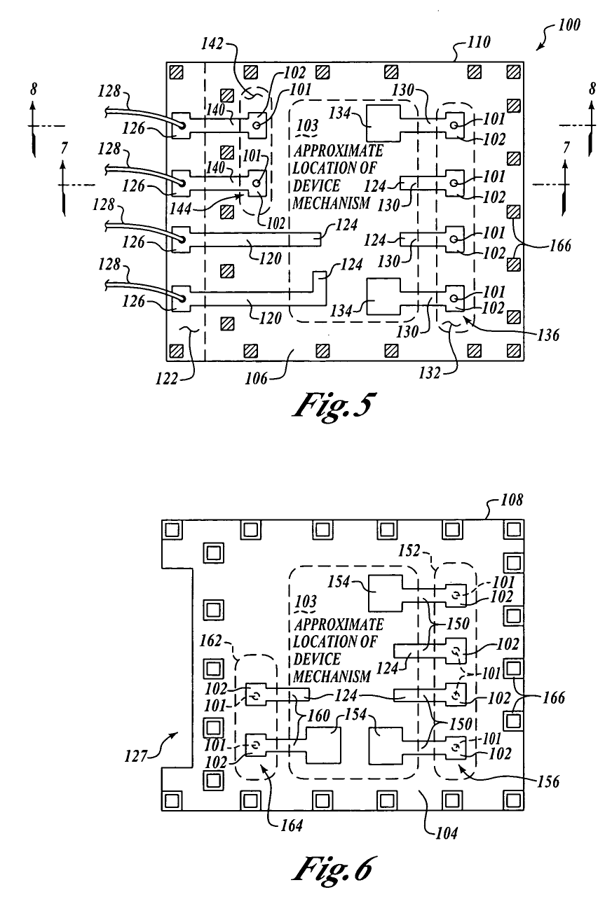

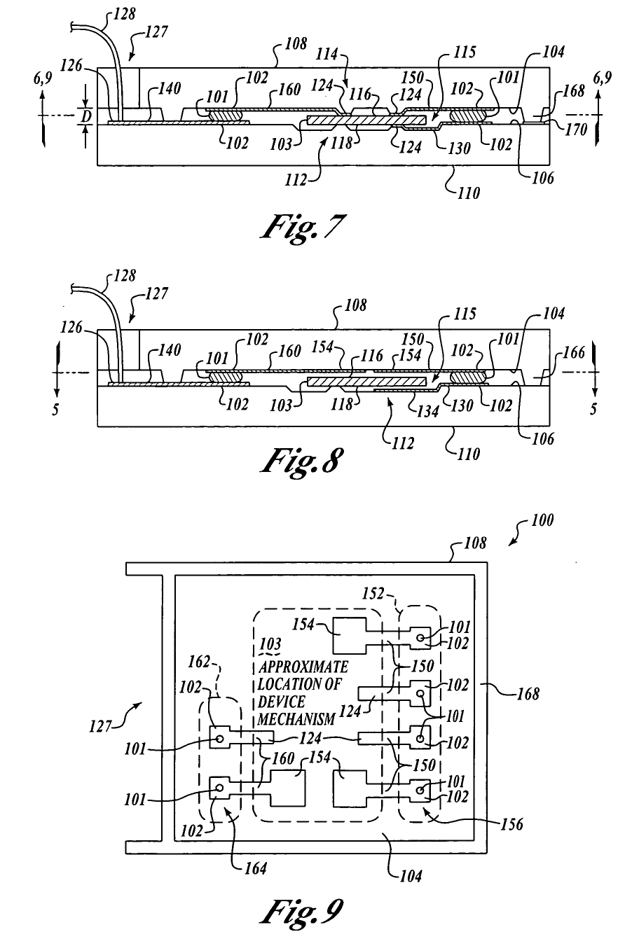

FIG. 5 is a top plan view of the device 100 with the top cover plate removed for clarity, and FIG. 6 is a bottom plan view of the device 100 with the bottom cover plate removed for clarity. FIG. 7 and FIG. 8 are different cross-sectional side views. FIGS. 5-8 all illustrate the present invention embodied in the micro-electromechanical system (MEMS) device 100 having a plurality of electrically conductive gold stud bumps 101 formed on individual electrical and mechanical interconnection areas 102 embodied as metal chip bond pads for forming electrically conductive paths between the top and bottom portions of the device while mechanically attaching the top substrate or cover plate to the bottom substrate or cover plate.

In FIG. 5 the MEMS device 100 is shown without its top cover and with the MEMS sensor or actuator device mechanism 103 removed for clarity. The MEMS device 100 includes a MEMS sensor or actuator device mechanism 103 bonded to one or both respective substantially planar inner surfaces 104 and 106 of a top substrate or cover plate 108 (shown in FIG. 6) and a bottom substrate or cover plate 110 at a position indicated generally by the dashed-line enclosure. The bottom cover plate 110, and optionally the top cover plate 108, is relieved to provide appropriate respective mechanism support and relief structures 112, 114 (shown in FIG. 8) that cooperate with the MEMS device mechanism 103.

The MEMS device mechanism 103 is patterned in a mechanism substrate or layer 115 (shown in FIGS. 7 and 8) which is optionally an epitaxial layer of semiconductor silicon grown on a silicon wafer of which either the top or bottom cover plate 108, 110 is formed. The mechanism substrate or layer 115 is formed having substantially planar and parallel spaced apart top and bottom surfaces 116, 118. When the MEMS device 100 utilizes silicon-to-glass anodic bonding for bonding the semiconductor silicon mechanism substrate or layer 115, one or both the top and bottom cover plates 108, 110 may be formed in respective Pyrex R™ glass wafers of a type having a thermal expansion coefficient substantially matched to that of silicon. Alternatively, as is well-known in the prior art, silicon-to-glass anodic bonding can be utilized when the top and bottom cover plates 108, 110 are formed in respective silicon substrates having thin glass films deposited thereon, as by sputtering. When the MEMS device is a SOI chip having the mechanism substrate or layer 115 as a silicon layer separated by an insulator layer from a silicon substrate layer forming the cover plates, the cover plates 108, 110 are silicon cover plates and are either silicon-to-silicon fusion boned or electrostatic silicon-to-silicon dioxide bonded, both well-known in the art.

One or more internal electrically conductive paths 120, for example electrical conductors embodied as gold traces, are electrically interconnected to the device mechanism 103 and extend outwardly to a remote area 122 of the inner surface 106 of the bottom cover plate 110 that is spaced away from the device mechanism 103 and external to the device seal which is discussed below. As disclosed in the prior art, the electrical conductors 120 may be partially submerged in the bottom cover plate 110 within shallow troughs or channels formed in the cover plate inner surface 106. Typically, the gold traces of which the electrical conductors 120 are formed extend above the cover plate inner surface 106 by about 500 to 1,000 Angstroms. One or more of the electrical conductors 120 includes an electrical interconnection area 124 embodied as an electrical contact formed of electrically conductive gold at a respective first end of the gold trace conductors 120 adjacent to the device mechanism 103 and projected above the bottom cover plate inner surface 106 generally. These electrical interconnection areas or contacts 124 are crushed or mashed against the bottom surface 118 of the MEMS device mechanism 103 or otherwise electrically interconnected to the device mechanism 103 during assembly to the bottom cover plate 110. The electrical contacts 124 thus make electrical connections to the semiconductor material of the MEMS device mechanism 103 of a type that is well-known in the prior art.

According to the present invention, each of the gold trace electrical conductors 120 further includes different electrical interconnection areas 126 embodied as conventional metal wire bond pads that are formed at a second end of the gold trace electrical conductors 120 and above the inner surface 106 of the bottom cover plate 110 in the remote area 122 spaced away from the device mechanism 103 and external to the device seal which is discussed below. One or more pass-through cover windows 127 (shown in FIG. 6) are formed in the top cover plate 108 to permit access to the remote area 122 of the bottom cover plate 110 and to the different wire bond pads 126. Different electrical wires 128 are wire bonded to the wire bond pads 126 for routing signals into and out of the device 100 without interfering with the device mechanism 103.

Alternatively, the conductors 120 are formed as buried diffused conductors doped by ion implantation, as described in co-pending U.S. patent application Ser. No. 10/226,518, HERMETICALLY SEALED SILICON MICRO-MACHINED ELECTROMECHANICAL SYSTEM (MEMS) DEVICE HAVING DIFFUSED CONDUCTORS, the complete disclosure of which is incorporated herein by reference. Accordingly, the electrical conductors 120 are formed as buried diffused conductors coupled via contact diffusions to the metal interconnection areas. Optionally, the diffused conductors are buried under an epitaxial layer and are electrically coupled to the metal interconnection areas 124, 126 via contact diffusions and contact holes in a passivation layer, as described by Jakobsen et al. in U.S. Pat. No. 5,591,679, SEALED CAVITY ARRANGEMENT METHOD, the complete disclosure of which is incorporated herein by reference. Signal routing is alternatively accomplished by means of electrical traces in combination with pillars of semiconductor silicon and corresponding cover plate windows as disclosed in co-pending U.S. patent application Ser. No. 10/746,463, SIGNAL ROUTING IN A HERMETICALLY SEALED MEMS DEVICE, the complete disclosure of which is incorporated herein by reference.

According to one embodiment of the invention illustrated in FIG. 5, one or more different individual internal electrically conductive paths or electrical conductors 130, for example electrical conductors embodied as gold traces, are formed on or in the inner surface 106 of the bottom cover plate 110 as described herein in connection with the conductors 120. Each of the electrical conductors 130 are electrically interconnected to the device mechanism 103, as described herein, and extend outwardly to a remote area 132 of the inner surface 106 of the bottom cover plate 110 that is external of the MEMS device mechanism 103 and spaced away therefrom but within the limits of the device seal which is discussed below.

One or more of the electrical conductors 130 includes one of the electrical interconnection areas 124 embodied as an electrical contact formed of electrically conductive gold at a respective first end of the gold trace conductors 130 adjacent to the device mechanism 103 and projected above the bottom cover plate inner surface 106 generally. As is discussed herein and is well-known in the prior art, these electrical interconnection areas or contacts 124 are crushed or mashed against the bottom surface 118 of the MEMS device mechanism 103 or otherwise electrically interconnected to the device mechanism 103 during assembly to the bottom cover plate 110. The electrical contacts 124 thus make electrical connections to the semiconductor material of the MEMS device mechanism 103 of a type that is well-known in the art.

Optionally, one or more of the electrical conductors 130 includes at its first end an electrode 134 formed on the inner surface 106 of the bottom cover plate 110 adjacent to the device mechanism 103. For example, the electrode 134 interacts with electrodes on the device mechanism 103 when the MEMS sensor or actuator device 100 is embodied as a capacitive sensor or actuator device.

Each of the electrical conductors 130 includes one of the electromechanical interconnection areas 102 embodied as a metal chip bond pad formed above the inner surface 106 of the bottom cover plate 110 in the remote area 132 to avoid interference with the MEMS device mechanism 103. As is well-known in the flip chip processing art, the electrically conductive gold ball stud bumps 101 can be placed on individual chip bond pad areas 102 measuring less than 75 microns. Accordingly, by example and without limitation, the individual chip bond pad areas 102 are optionally formed measuring about 75 microns or less, but may be larger or slightly smaller without materially affecting the practice of the invention. As is also well-known in the flip chip processing art, pitches of less than 100 microns are easily achievable. Therefore, by example and without limitation, the individual chip bond pad areas 102 are optionally provided at a pitch of about 100 microns or less, but the pitch may be larger or slightly smaller without materially affecting the practice of the invention. One of the electrically conductive gold stud bumps 101 is accordingly formed on each of the individual chip bond pad areas 102, as described herein. The chip bond pad areas 102 and stud bumps 101 are provided in an appropriate pattern 136 structured to cooperate with corresponding electromechanical interconnection areas 102 embodied as bond pad areas formed on the inner surface 104 of the top substrate or cover plate 108, as discussed herein.

According to the gold stud bumping process of the invention gold stud bumps are placed on the different chip bond pad areas 102 using a well-known modification of the “ball bonding” process used in conventional wire bonding. In ball bonding, the tip of the gold bond wire is melted to form a sphere. The wire bonding tool presses this sphere against the chip bond pad area 102, applying mechanical force, heat, and ultrasonic energy to create a metallic connection. The wire bonding tool next extends the gold wire to the chip bond pad area 102 and makes a “stitch” bond to that pad, finishing by breaking off the bond wire to begin another cycle.

For gold stud bumping, the first ball bond is made as described, but the wire is then broken close above the ball 101. The resulting gold ball 101, or “stud bump” remaining on the chip bond pad area 102 provides a permanent, reliable connection to the corresponding electrical conductor 130. The bump diameter at the base is about 75 microns when formed using 0.001 inch diameter wire. The bump diameter may be smaller when using smaller wire, and may be substantially larger when using larger wire, for example, 0.002 inch diameter wire.

After placing the stud bumps 101 on the chip bond pad area 102, the stud bumps 101 may be flattened or “coined” by mechanical pressure to provide a flatter top surface and more uniform bump heights. Flattening or coining also presses any remaining wire tail into the ball. Each bump 101 may be coined by a tool immediately after forming, or all bumps 101 on the die may be simultaneously coined by pressure against a flat surface in a separate operation following bumping.

According to another embodiment of the invention illustrated in FIG. 5, one or more different individual internal electrically conductive paths or electrical conductors 140, for example electrical conductors embodied as gold traces, are formed on or in the inner surface 106 of the bottom cover plate 110 as described herein in connection with the conductors 120. Each of the gold trace electrical conductors 140 extends between the remote area 122 of the bottom cover plate 110 and another remote area 142 of the inner surface 106 of the bottom cover plate 110 that is external of the MEMS device mechanism 103 and spaced away therefrom but within the limits of the device seal which is discussed below.

Each of the gold trace electrical conductors 140 includes at a first end one of the electromechanical interconnection areas 102 embodied as a metal chip bond pad formed as discussed herein in the remote area 142 of the bottom cover plate 110 to avoid interference with the MEMS device mechanism 103. One of the electrically conductive gold stud bumps 101 is accordingly formed on each of the individual chip bond pad areas 102, as described herein. The chip bond pad areas 102 and stud bumps 101 are provided in an appropriate pattern 144 structured to cooperate with corresponding electromechanical interconnection areas 102 embodied as bond pad areas formed on the inner surface 104 of the top substrate or cover plate 108, as discussed herein.

At a second in the remote area 122 of the bottom cover plate 110 each of the gold trace electrical conductors 140 includes one of the electrical interconnection areas 126 embodied as a conventional metal wire bond pad. Different electrical wires 128 are wire bonded to the wire bond pads 126 for routing signals into and out of the device 100 without interfering with the device mechanism 103.

FIG. 6 is a bottom plan view of the device 100 with the bottom cover plate 110 removed for clarity and thereby showing the inner surface 104 of the top substrate or cover plate 108. According to one embodiment of the invention, the inner surface 104 of the top cover plate 108 is formed with one or more different individual internal electrically conductive paths or electrical conductors 150, for example electrical conductors embodied as gold traces, as described herein in connection with the conductors 120, 130. One or more of the electrical conductors 150 are electrically interconnected to the device mechanism 103, as described herein, by one of the electrical interconnection areas 124 embodied as an electrical contact formed of electrically conductive gold at a respective first end the electrical conductors 150. The electrical conductors 150 extend outwardly to a remote area 152 of the inner surface 104 of the top cover plate 108 that is external of the MEMS device mechanism 103 and spaced away therefrom but is within the limits of the device seal which is discussed below. The remote area 152 corresponds to the remote area 142 of the inner surface 106 of the bottom cover plate 110 (shown in FIG. 5) where the electromechanical interconnection areas 102 of the electrical conductors 140 are located.

One or more of the electrical conductors 150 optionally includes at its first end an electrode 154 formed on the inner surface 104 of the top cover plate 108 adjacent to the device mechanism 103. For example, the electrode 154 interacts with electrodes on the device mechanism 103 when the MEMS sensor or actuator device 100 is embodied as a capacitive sensor or actuator device.

Each of the electrical conductors 150 includes one of the electromechanical interconnection areas 102 embodied as a metal bond pad formed above the inner surface 104 of the top cover plate 108 in the remote area 152 to avoid interference with the MEMS device mechanism 103. As is well-known in the flip chip processing art and discussed herein, the electrically conductive gold ball stud bumps 101 can be placed on individual bond pad areas 102 measuring less than 75 microns. Accordingly, by example and without limitation, the individual chip bond pad areas 102 are optionally sized about 75 microns or larger, but may be slightly smaller without materially affecting the practice of the invention. As discussed herein, the stud bumps 101 are used with the top and bottom electrical conductors 150, 130 for communicating between the opposing top and bottom surfaces of the MEMS device mechanism 103, except in the case of the top and bottom electrical conductors 150, 130 having electrodes 154, 134 formed at their respective first ends where the stud bumps 101 are used for communicating between the opposing inner surfaces 104, 106 of the top and bottom cover plates 108, 110. Accordingly, the chip bond pad areas 102 of the electrical conductors 150 are formed in pattern 156 positioned in the remote area 152 of the top cover plate 108 to interconnect with the pattern 136 of electrically conductive gold ball stud bumps 101 formed on the electromechanical interconnection areas 102 of the electrical conductors 130 on the inner surface 106 of the bottom substrate or cover plate 110, as discussed herein. Accordingly, each of electrically conductive gold ball stud bumps 101 (indicated by phantom lines) mechanically and electrically interconnects with one of the chip bond pad areas 102 of the electrical conductors 150 during assembly of the top and bottom cover plates 108, 110 of the MEMS device 100. As shown in FIGS. 7 and 8, electrical communication is thereby accommodated between the top and bottom surfaces 116, 118 of the MEMS device mechanism 103 through the electrically conductive gold ball stud bumps 101 interconnecting the respective internal electrically conductive paths or electrical conductors 150, 130 of the top and bottom cover plates 108, 110. Optionally, in the case of the top and bottom electrical conductors 150, 130 having electrodes 154, 134 formed at their respective first ends, electrical communication is thereby accommodated between the inner surfaces 104, 106 of the top and bottom cover plates 108, 110.

According to another embodiment of the invention, the inner surface 104 of the top cover plate 108 is formed with one or more different individual internal electrically conductive paths or electrical conductors 160, for example electrical conductors embodied as gold traces, as described herein in connection with the other top cover plate conductors 150. One or more of these electrical conductors 160 extends between one of the device mechanism interconnection areas 124 and one of the chip bond pad areas 102 in another remote area 162 of the top cover plate 108 that is external of the MEMS device mechanism 103 but within the limits of the device seal, as discussed herein, and corresponds to the remote area 142 of the inner surface 106 of the bottom cover plate 110. The chip bond pad areas 102 in the remote area 162 are formed in pattern 164 positioned in the remote area 162 of the top cover plate 108 to interconnect with the pattern 144 of electrically conductive gold ball stud bumps 101 formed on the electromechanical interconnection areas 102 of the electrical conductors 140 on the inner surface 106 of the bottom substrate or cover plate 110, as discussed herein. Accordingly, each of electrically conductive gold ball stud bumps 101 (indicated by phantom lines) mechanically and electrically interconnects with one of the chip bond pad areas 102 of the electrical conductors 150 during assembly of the top and bottom cover plates 108, 110 of the MEMS device 100.

According to another embodiment of the invention, one or more of the electrical conductors 160 optionally includes at its first end one of the electrodes 154 formed on the inner surface 104 of the top cover plate 108 adjacent to the device mechanism 103. As discussed herein, the electrode 154 may interact with electrodes on the device mechanism 103 when the MEMS sensor or actuator device 100 is embodied as a capacitive sensor or actuator device.

As discussed herein, one or more of the stud bumps 101 are used with the top and bottom electrical conductors 160, 140 for routing signals into and out of the device 100 by communicating between the top surface 116 of the MEMS device mechanism 103 and the wire bond pads 126 positioned in the remote area 122 external to the device seal. Accordingly, during assembly of the MEMS device 100, each of electrically conductive gold ball stud bumps 101 (indicated by phantom lines) mechanically and electrically interconnects with one of the chip bond pad areas 102 of the electrical conductors 160 of the top cover plate 108 with a corresponding one of the chip bond pad areas 102 of the electrical conductors 140 of the bottom cover plate 110. As shown in FIG. 7, routing of signals into and out of the top surface 116 of the MEMS device mechanism 103 is thereby accommodated through the electrically conductive gold ball stud bumps 101 interconnecting the respective internal electrically conductive path or electrical conductor 160 of the top cover plate 108 with the external electrically conductive path or electrical conductor 140 of the bottom cover plate 110.

Alternatively, in the case of the top electrical conductors 160 being formed at their first ends with electrodes 154, the stud bumps 101 instead accommodate electrical communication between the inner surface 104 of the top cover plate 108 and the external electrically conductive path or electrical conductor 140 of the bottom cover plate 110. In either case, signals are routed through the electrical conductor 140 to the wire bond pads 126 and the electrical wires 128.

Assembly

The gold stud bumped die, i.e., the top and bottom substrates or cover plates 108, 110 including the mechanism device 103 and the electrically conductive gold stud bumps 101, may be attached by conductive or non-conductive adhesives, or by thermocompressive, ultrasonic or thermosonic assembly without adhesive. Conductive adhesive may be isotropic, conducting in all directions, or anisotropic, conducting in a preferred direction only.

Isotropic conductive adhesives are well-known and well-characterized materials formed of an adhesive binder filled with conductive particles that are normally in contact with each other and provide minimal electrical resistance in all directions. Isotropic conductive adhesives are dispensed by stencil printing onto the substrate chip bond pads 102, or if the device mechanism does not contain sensitive moving parts, the bumped die are dipped into a thin layer of adhesive, whereby only the bumps are coated with adhesive.

Stenciled isotropic adhesive assembly is known to provide a larger quantity of adhesive than dipped assembly, whereby mechanically stronger bonds are formed. The additional adhesive compensates for minimal bump height variations. A panelized array of the bumped die may be simultaneously stenciled in one operation, which speeds assembly. The stenciled adhesive can be inspected or measured before die mount to insure uniformity. Stenciling requires a high-precision stencil printer and stencils which limits minimum pad pitch to about 90 microns, to allow adequate conductive adhesive transfer.

Dipping requires a thin, precisely controlled layer of adhesive, and co-planarity of the die and adhesive during the dipping process. Because dipping places adhesive only on the bump surface, the minimum bump spacing is smaller than for stenciling such that pad pitches of 60 microns or less may be utilized. Dipping does not require additional equipment as stenciling does because a die mount aligner-bonder can be used for dipping. However, dipping requires careful control of the adhesive layer thickness, and dipping is a serial process, which lengthens throughput time.

The isotropic conductive adhesive is heat cured, and thereafter a non-conducting underfill adhesive is optionally applied to completely fill the under-chip space, i.e., the space between the top and bottom substrates or cover plates 108, 110. The underfill adds mechanical strength to the assembly and protects the connections from environmental hazards. Underfill adhesive is dispensed along one or more edges of the die and is drawn into the space under the die through capillary action. Heat-curing the underfill adhesive completes the assembly process.

Non-conductive adhesive assembly is in some ways similar to anisotropic adhesive assembly. A non-conductive adhesive is dispensed or stenciled at the die location on the substrate. The bumped die 108, 110 is pressed against the substrate chip bond pads 102 with enough force give compressive dispersion of the adhesive, allowing no adhesive to remain between the mating surfaces of the stud bump 101 and substrate chip bond pad 102. This pressure is maintained during bake at an elevated temperature for sufficient time to at least partially cure the adhesive. The top and bottom substrates 108, 110 are mechanically bonded to one another by the cured adhesive, with metal-to-metal contact between the bumps 101 and substrate chip bond pads 102. No separate underfill adhesive is required. Non-conductive adhesive has advantages for assembly onto flexible substrates, since the adhesive is cured while in the aligner-bonder which maintains the fixed die location. Dispensing the adhesive properly and repeatably requires automated equipment, and the aligner-bonder throughput is determined by curing time, including ramping up and down from the curing temperature. While semiconductor devices that are commonly back-filled with epoxy to protect them from contamination and handling damage, back-filling with epoxy would constrain the moving parts of accelerometer sensors and other micromechanical actuator device mechanisms and thereby render them inoperative. Likewise, adhesive improperly placed during assembly could interfere with moving parts of the device mechanism 103. Therefore, in contrast to semiconductor devices, thermocompressive or ultrasonic assembly is preferred when the device mechanism 103 is a sensor or actuator device having moving parts, such as a capacitive or vibrating beam acceleration sensor. Ultrasonic assembly eliminates the adhesive from device mechanism 103 that cannot tolerate adhesives against their active surfaces. Non-adhesive assembly for the gold stud bumped die 110 (or 108) is accomplished by pressing the bumped die 110 (or 108) onto the gold chip bond pads 102 of the un-bumped substrate 108 (or 110) and applying heat and pressure sufficient to form gold-to-gold metallic bonds between the stud bumps 101 and the gold chip bond pads 102 as in thermocompressive wire bonding. Optionally sonic energy is used in combination with the heat and pressure in an amount sufficient to form gold-to-gold metallic bonds between the stud bumps 101 and the gold chip bond pads 102 as in thermosonic wire bonding. When the stud bumps 101 are initially formed as gold balls in the range of about 50 to 75 micrometers tall, the heat, pressure, and sonic energy applied during ultrasonic assembly compresses the stud bumps 101 to about the thickness of the MEMS device mechanism 103, i.e., the thickness of the mechanism substrate or layer 115, shown in FIGS. 7, 8. The stud bumps 101 are alternatively stacked, as is known in the art, to vary the resultant spacing. Thus, spacing between the device mechanism 103 and the opposing top or bottom cover plate 108, 110 is set in a controlled manner that will provide symmetric air gaps which tends to improves performance, particularly in vibration environments, in devices having moving parts, such as vibrating beam accelerometer sensors.

In semiconductor devices the stud bumps 101 can be used to space the top and bottom substrates or cover plates 108, 110. This method may also be used in MEMS devices when the device mechanism 103 contains no moving parts that are sensitive to mechanical interferences. However, when the device mechanism 103 is a sensor or actuator device having moving parts, such as a capacitive or vibrating beam acceleration sensor, that cannot tolerate inadvertent constraints, the designer may choose other means for setting the spacing between the cover plates 108, 110. For example, a plurality of mesas 166 are formed in one or both of the top cover plate 108 (shown) and bottom cover plate 110. The plurality of mesas 166 are formed in one of the cover plates 108 (or 110) in a pattern around the device mechanism 103, as is well-known in the art. The mesas 166 are alternatively used in a capacitive read-out device that relies upon capacitance between the device mechanism 103 and conductive pads or electrodes on the cover plates 108, 110. Because the electrode area is limited to the area under the device mechanism, providing the opposing cover plate 108 (or 110) at a precise distance from the device mechanism 103 permits the mechanism area opposite the second or top cover plate 108 (or bottom cover plate 110) to be used in addition to the area opposite the bottom cover plate 110 (or top cover plate 108). Thus, the electrodes 154 on the top cover plate 108 (or electrodes 134 on the bottom cover plate 110) can be used to effectively double the maximum area for capacitive interaction between the device mechanism 103 and the cover plates 108, 110. This greatly increased capacitive interaction area makes designs possible that are unknown in the prior art because of the limitations of current technology. By example and without limitation, by providing the electrodes 154 on the top cover plate 108 in combination with the electrodes 134 on the bottom cover plate 110, the present invention provides usable capacitive area on both the upper and lower surfaces 116, 118 of the device mechanism 103, which greatly simplifies closed loop sensor designs. The present invention also renders such designs more effective since restoring forces applied using electrostatic attraction can be applied on both upper and lower surfaces 116, 118 of the device mechanism 103. Accordingly, the mesas 166 are formed in one or both of the top and bottom cover plates 108, 110 such that the top and bottom cover plates 108, 110 are spaced apart a precise distance D (shown in FIG. 7). This precise spacing D causes the top and bottom cover plates 108 110 to each be precisely symmetrically spaced from the respective upper and lower surfaces 116, 118 of the device mechanism 103.

FIG. 9 is an upward-looking bottom plan view of the device 100 of the present invention embodied with the gold ball stud bumps 101 and device mechanism 103 provided on the top substrate or cover plate 108. In FIG. 9, the device 100 is shown with the bottom substrate or cover plate 110 removed for clarity. According to one embodiment of the invention, the top substrate or cover plate 108 includes a continuous mesa 168 formed in a pattern around the device mechanism 103. The continuous mesa 168 provides an environmental seal encompassing the device mechanism 103 and operating as a dust cover for protection from particulate contamination when the device mechanism 103 is embodied having moving parts, such as an accelerometer sensor or other micromechanical actuator, that cannot tolerate particulate contamination against their active surfaces.

Optionally, a hermetic seal is obtained using a small amount of bonding material 170, such as frit, adhesive, or epoxy, between the mesa and the opposing substrate or cover plate 110 (or 108) to completely seal therebetween.

While the preferred embodiment of the invention has been illustrated and described, it will be appreciated that various changes can be made therein without departing from the spirit and scope of the invention.

1. A micro-electromechanical system (MEMS) device, comprising:
a pair of spaced apart top and bottom substrates having mutually opposing inner surfaces;
a micro-machined electromechanical device mechanism coupled to the inner surface of one of the top and bottom substrates;
a metal chip bond pad formed on the inner surface of the bottom substrate and being electrically coupled to an electrical path;
a metal chip bond pad formed on the inner surface of the top substrate in a complementary position opposite the chip bond pad on the bottom substrate; and
a gold stud bump mechanically and electrically coupled between the chip bond pads on the top and bottom substrates.

2. The device of claim 1 wherein the top and bottom substrates are symmetrically spaced from active surfaces of the micro-machined electromechanical device.

3. The device of claim 1, further comprising a metal wire bond pad formed on the inner surface of the bottom substrate remote from the device mechanism and being electrically coupled to the electrical path.

4. The device of claim 1, further comprising an electrical path formed on the inner surface of the top substrate and being electrically coupled to the chip bond pad.

5. The device of claim 4 wherein the electrical path formed on the inner surface of the top substrate is further electrically coupled to an upper surface of the device mechanism.

6. The device of claim 5 wherein the electrical path formed on the inner surface of the bottom substrate is further electrically coupled to a lower surface of the device mechanism.

7. The device of claim 1, further comprising a mesa formed on the inner surface of one of the top and bottom substrates.

8. The device of claim 7 wherein the mesa further comprises a continuous mesa completely surrounding the device mechanism.

9. The device of claim 8, further comprising a seal formed between the mesa and the inner surface of one of the top and bottom substrates.

10. A micro-electromechanical system (MEMS) device, comprising:
first and second spaced apart substrates having first and second mutually opposing inner surfaces;
a semiconductor silicon mechanism substrate mechanically coupled to one of the inner surfaces and having a micro-electromechanical device mechanism patterned therein;
a plurality of pairs of complementary chip bond pads formed on the first and second mutually opposing inner substrate surfaces;
a gold stud bump thermocompressively or ultrasonically coupled between each of the pairs of complementary chip bond pads.

11. The device of claim 10, further comprising:
a first electrical conductor formed on the first of the mutually opposing inner substrate surfaces and being electrically coupled to a first one of the chip bond pads of one of the pairs of complementary chip bond pads;
and a second electrical conductor formed on the second of the mutually opposing inner substrate surfaces and being electrically coupled to a second one of the pair of complementary chip bond pads.

12. The device of claim 11 wherein each of the first and second electrical conductors further comprises an electrical contact being electrically coupled to the device mechanism.

13. The device of claim 11 wherein one of the first and second electrical conductors further comprises a conventional wire bond pad formed on the corresponding inner substrate surface at a position remote from the device mechanism.

14. The device of claim 13 wherein a different one of the first and second electrical conductors further comprises an electrical contact being electrically coupled to the device mechanism.

15. The device of claim 11, further comprising an electrode formed on one of the first and second mutually opposing inner substrate surfaces opposite from a portion of the device mechanism and being electrically coupled to a corresponding one of the first and second electrical conductors.

16. The device of claim 10 wherein the first and second mutually opposing inner substrate surfaces are spaced substantially symmetrically from respective first and second surfaces of the mechanism substrate.

17. The device of claim 16, further comprising one or more mesas formed between the first and second mutually opposing inner substrate surfaces.

18. The device of claim 17, further comprising a hermetic seal between the first and second mutually opposing inner substrate surfaces and completely surround the micro-electromechanical device mechanism.

19. A micro-electromechanical system (MEMS) capacitive acceleration sensor device, comprising:
a pair of mutually spaced apart first and second substrates having mutually opposing inner surfaces;
a semiconductor silicon mechanism substrate mechanically coupled to one of the inner surfaces and having a micro-machined capacitive acceleration sensor mechanism patterned therein;
one or more electrodes formed on each of the first and second mutually opposing inner substrate surfaces;
one or more pairs of complementary metal chip bond pads formed on the first and second mutually opposing inner substrate surfaces;
an electrically conductive path formed between one of the electrodes and one of the chip bond pads on a corresponding one of the first and second mutually opposing inner substrate surfaces;
a gold stud bump electrically and mechanically coupled between each of the pairs of complementary metal chip bond pads; and
one or more mesas spacing the electrodes on the first and second mutually opposing inner substrate surfaces substantially symmetrically from respective first and second surfaces of the capacitive acceleration sensor mechanism.

20. The device of claim 19, further comprising an electrically conductive path coupled between the capacitive acceleration sensor mechanism and one of the chip bond pads.

21. The device of claim 19, further comprising:
a plurality of wire bond pads formed on one of the first and second mutually opposing inner substrate surfaces; and
an electrically conductive path formed between one of the chip bond pads and one of the wire bond pads.

22. The device of claim 21 wherein:
the semiconductor silicon mechanism substrate having the micro-machined capacitive acceleration sensor mechanism patterned therein is mechanically coupled to the inner surface of the first substrate;
the one or more mesas extend from the inner surface of the first substrate; and
the plurality of wire bond pads are formed on the inner surface of the second substrate in an area remote from the sensor mechanism.
